(19) United States
(12) Patent Application Publication
(10) Pub. No.: US 2014/0231250 A1
(43) Pub. Date: Aug. 21, 2014

(54) C PARTICLE DISPERSED FE-PT-BASED SPUTTERING TARGET

(71) Applicant: JX NIPPON MINING & METALS CORPORATION, Tokyo (JP)

(72) Inventors: Shin-ichi Ogino, Ibaraki (JP); Atsushi Sato, Ibaraki (JP); Yuichiro Nakamura, Ibaraki (JP)

(21) Appl. No.: 14/346,355

(22) PCT Filed: Dec. 18, 2012
(86) PCT No.: PCT/JP2012/082795

§ 371 Date: Mar. 21, 2014

(30) Foreign Application Priority Data
Dec. 22, 2011 (JP) 2011-281070

(51) Int. Cl. C23C 14/34

(52) U.S. Cl. CPC C23C 14/3414
USPC 204/298.13

(57) ABSTRACT

Provided is a sputtering target for a magnetic recording film, the sputtering target comprising 5 mol % or more and 60 mol % or less of Pt, 0.1 mol % or more and 40 mol % or less of C, 0.05 mol % or more and 20 mol % or less of titanium oxide, and the remainder being Fe. It is an object of the present invention to provide a high-density sputtering target that can produce a granular magnetic thin film without using any high-cost co-sputtering apparatuses and can also reduce the amount of particles generated during sputtering.

### TECHNICAL FIELD

The present invention relates to a sputtering target that is used for forming a granular magnetic thin film in a magnetic recording medium and specifically relates to a C particle dispersed Fe—Pt-based sputtering target.

### BACKGROUND

In the field of magnetic recording represented by hard disk drives, ferromagnetic metal materials, i.e., Co, Fe, or Ni-based materials, are used as materials of magnetic thin films in magnetic recording media. For example, in the magnetic thin film of a hard disk employing a longitudinal magnetic recording system, a Co—Cr-based or Co—Cr—Pt-based ferromagnetic alloy mainly composed of Co has been used.

In magnetic thin films of hard disks employing a perpendicular magnetic recording system that has been recently applied to practical use, composite materials each composed of a Co—Cr—Pt-based ferromagnetic alloy mainly composed of Co and nonmagnetic inorganic particles are widely used. In many cases, the magnetic thin film is produced by sputtering a sputtering target composed of the above-mentioned material with a DC magnetron sputtering apparatus because of its high productivity.

Incidentally, the recording density of a hard disk is rapidly increasing year by year, and it is predicted that the areal recording density will reach 1 Tbit/in² in the future, whereas the current areal recording density is 600 Gbit/in². In order to achieve a recording density of 1 Tbit/in², the recording bit size must be reduced to 10 nm or less. In such a case, a problem of superparamagnetization by thermal fluctuation is predicted. The magnetic recording medium materials currently used, e.g., Co—Cr-based alloys having enhanced magnetic crystalline anisotropy by containing Pt therein, are predicted to be insufficient for preventing the problem, and magnetic particles that behave as a stable ferromagnetic material in a size of 10 nm or less need to have higher magnetic crystalline anisotropy.

Based on the above-described circumstances, a Fe—Pt phase having a L1₀ structure has attracted attention as a material for ultra-high density recording media. The Fe—Pt phase having a L1₀ structure has not only high magnetic crystalline anisotropy but also excellent corrosion resistance and oxidation resistance and is therefore expected as a material that can be applied to magnetic recording media. In order to use the Fe—Pt phase as a material for an ultra-high density recording medium, it is necessary to develop a technology of dispersing Fe—Pt magnetic particles regulated in the same direction with a density as high as possible in a magnetically isolated state.

From these circumstances, a granular magnetic thin film in which Fe—Pt magnetic particles having a L1₀ structure are isolated from one another by a nonmagnetic material such as an oxide or carbon has been proposed as a magnetic film for a magnetic recording medium of the next-generation hard disk employing a thermally assisted magnetic recording system. The granular magnetic thin film has a structure in which the magnetic particles are magnetically isolated from one another by means of the intervention of a nonmagnetic material. Magnetic recording media including magnetic thin films having granular structures and documents regarding them are described in Patent Literatures 1 to 5, for example.

Among the granular magnetic thin films including a Fe—Pt phase having the L1₀ structure, a magnetic thin film containing 10 to 50% by volume of C as a nonmagnetic material has particularly attracted attention from its high magnetic characteristics. Such a granular magnetic thin film is known to be produced by simultaneously sputtering a Fe target, a Pt target, and a C target or simultaneously sputtering a Fe—Pt alloy target and a C target. In order to simultaneously sputtering these sputtering targets, however, a high-cost co-sputtering apparatus is necessary.

In general, sputtering of a sputtering target containing a nonmagnetic material in an alloy with a sputtering apparatus has problems of causing unintended detachment of the nonmagnetic material during the sputtering or occurrence of particles (dust adhered to a substrate) due to abnormal discharge occurring from holes present in the sputtering target. In order to solve these problems, it is necessary to enhance the adhesiveness between the nonmagnetic material and the base alloy and to increase the density of the sputtering target. In general, the sputtering target material of an alloy containing a nonmagnetic material is produced by a powder sintering method. However, in the case of a Fe—Pt containing a large amount of C, preparation of a sintered compact having a high density has been difficult, since C is a material of which sintering is difficult.

The density of a sintered compact being low indicates that the sintered compact contains a large number of holes (pores). The holes serve as starting points of abnormal discharge during sputtering and cause occurrence of particles. Accordingly, an increase in density of the sintered compact is required. In addition, carbon has a property of easily aggregating, and the aggregated carbon material also causes occurrence of particles during sputtering. Furthermore, C detaches from the alloy phase of a target during sputtering, which also causes occurrence of particles. As described above, in Fe—Pt-based magnetic material targets, it has been demanded to solve the to problems caused by C.

### CITATION LIST

### Patent Literature

Patent Literature 1: Japanese Patent Laid-Open No. 2000-306228
Patent Literature 2: Japanese Patent Laid-Open No. 2000-311329
Patent Literature 3: Japanese Patent Laid-Open No. 2008-59733
Patent Literature 4: Japanese Patent Laid-Open No. 2008-169464
Patent Literature 5: Japanese Patent Laid-Open No. 2004-152471

### SUMMARY OF THE INVENTION

### Technical Problem

It is an object of the present invention to provide a C particle-dispersed Fe—Pt-based sputtering target that can produce a granular magnetic thin film without using any high-cost co-sputtering apparatuses. It is also an object of the invention to provide a high-density sputtering target that generates a reduced amount of particles during sputtering.

### Solution to Problem

The present inventors have diligently studied for solving the problems and, as a result, have found that a high-density sputtering target can be produced by uniformly and finely dispersing C particles as a nonmagnetic material in a base metal through simultaneous addition of titanium oxide. The thus-produced sputtering target can considerably reduce the occurrence of particles. That is, it has been found that the yield of film formation can be increased.

The present invention, based on these findings, provides the following aspects:

1) A sputtering target for a magnetic recording film, the sputtering target comprising 5 mol % or more and 60 mol % or less of Pt, 0.1 mol % or more and 40 mol % or less of C, 0.05 mol % or more and 20 mol % or less of titanium oxide, and the remainder being Fe;

2) The sputtering target for a magnetic recording film according to 1) above, wherein titanium oxide particles are dispersed in the target; and the C is partially solid-soluted in the titanium oxide particles or is partially included in oxide particles;

3) The sputtering target according to 1) above, wherein element mapping of a polished surface of the sputtering target shows that a region where both titanium (Ti) and oxygen (O) are detected includes a part of a region where C is detected;

4) The sputtering target for a magnetic recording film according to any one of 1) to 3) above, the sputtering target further comprising 0.5 mol % or more and 20 mol % or less of at least one additional element selected from B, Ru, Ag, Au, and Cu; and the remainder being Fe;

5) The sputtering target for a magnetic recording film according to any one of 1) to 4) above, the sputtering target further comprising 0.5 mol % or more and 20 mol % or less of at least one oxide additive selected from SiO₂, Cr₂O₃, CoO, Ta₂O₅, B₂O₃, MgO, and Co₃O₄; and the remainder being Fe; and

6) The sputtering target for a magnetic recording film according to any one of 1) to 5) above, the sputtering target having a relative density of 97% or more.

### Effects of Invention

The C particle dispersed Fe—Pt alloy-based sputtering target of the present invention allows production of a granular magnetic thin film without using any high-cost co-sputtering apparatuses, and the present invention has an excellent effect capable of providing a high-density sputtering target reducing the amount of particles generated during sputtering by uniformly and finely dispersing C particles, which are prone to aggregate, in a base metal.

### BRIEF DESCRIPTION OF THE DRAWINGS

FIG. 1 is images showing an appearance that regions where both titanium (Ti) and oxygen (O) are detected include a part of regions where C is detected in element mapping of a polished surface of a sputtering target containing titanium oxide.

### DETAILED DESCRIPTION OF THE EMBODIMENTS

The sputtering target for a magnetic recording film of the present invention is composed of 5 mol % or more and 60 mol % or less of Pt, 0.1 mol % or more and 40 mol % or less of C, 0.05 mol % or more and 20 mol % or less of titanium oxide, and the remainder being Fe. This composition is the basis of the present invention.

In the present invention, the content of C particles in the sputtering target composition is preferably 0.1 mol % or more and 40 mol % or less. A content of C particles in the target composition of less than 0.1 mol % may provide unsatisfactory magnetic characteristics, whereas a content exceeding 40 mol % may cause aggregation of C particles to increase the occurrence of particles, even if the composition is of the present invention.

In addition, in the present invention, the content of Pt in the Fe—Pt-based alloy composition is 5 mol % or more and 60 mol % or less. A content of Pt in the Fe—Pt-based alloy of less than 5 mol % may provide unsatisfactory magnetic characteristics. Similarly, a content exceeding 60 mol % may provide unsatisfactory magnetic characteristics.

The content of titanium oxide is 0.05 mol % or more and 20 mol % or less. A content of less than 0.05 mol % causes aggregation of C particles and loses the effect of suppressing the occurrence of particles. A content exceeding 20 mol % may provide unsatisfactory magnetic characteristics and is therefore preferably defined as the upper limit.

The carbon (C) added to the target for improving the magnetic characteristics exists in the Fe—Pt-based alloy target in a special form. That is, the majority of the C particles exist together with titanium oxide dispersed in the target.

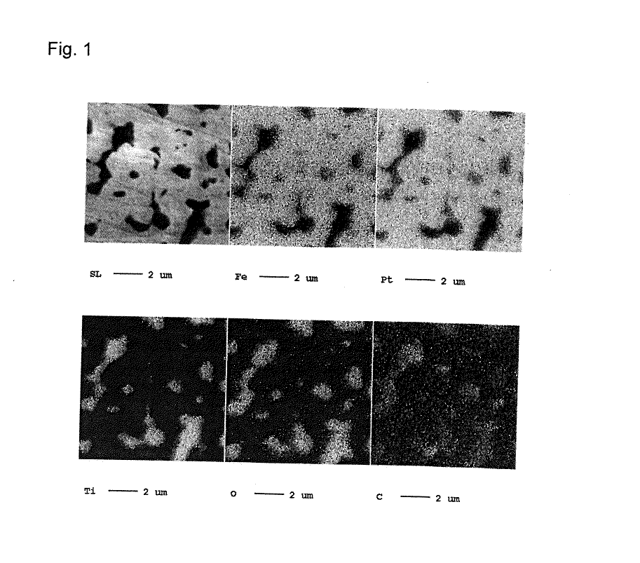

In element mapping of the polished surface of the sputtering target of the present invention, regions where C is detected appear within regions where both titanium (Ti) and oxygen (O) are detected. FIG. 1 shows such appearance. As obvious from FIG. 1, the majority (at least a part) of the C particles are included in titanium oxide.

It is believed that C is present in the titanium oxide particles dispersed in the target in a form such that a part of C is solid-soluted or is included in the oxide particles. This means that the titanium oxide at least lies between carbon materials. This existence form is based on a prerequisite that the target contains dispersed titanium oxide particles and is a significantly special form.

Carbon has sinterability higher than that of titanium oxide. Therefore, titanium oxide including at least a part of C or lying between carbon particles is improved in sinterability, resulting in an increase in the total density of the resulting sintered compact. In addition, the C particles are inhibited from aggregating to increase the dispersibility of the carbon material. As a result, an effect of reducing the particles caused by aggregation of carbon is obtained.

In addition, in the sputtering target of the present invention, C particles are desirably composed of graphite. A sputtering target containing graphitic C particles has an effect of further reducing the occurrence of particles.

This is, however, not an important issue, as long as C particles are contained, and any type of C particles can be used.

A relative density of 97% or more is one of important matters in the present invention and can be achieved in the sputtering target of the present invention. A higher relative density reduces disadvantages due to degassing from the sputtering target during sputtering and increases adhesiveness between an alloy and C particles to effectively suppress the occurrence of particles.

It is desirable that the average area per particle in the portion other than the alloy phase of the sputtering target is as small as possible. A small average area per particle has an effect of shortening the burn-in time for sputtering. This point will be described in the following examples as preferable conditions.

The relative density in the present invention is the value determined by dividing the observed density of a target by the calculated density (also referred to as theoretical density). The calculated density is the density based on the assumption that the components of a target are present as a mixture without diffusing to or reacting with each other and is calculated by the following expression:

calculated density=Σ[(molecular weight of a component)×(molecular ratio of the component)]/Σ[(molecular weight of a component)×(molecular ratio of the component)/(literature density data of the component)], Expression:

wherein, Σ means the sum of the values of all components of the target.

The sputtering target of the present invention is produced by a powder sintering method. Prior to the production, each raw material powder (a Fe powder, a Pt powder, a titanium oxide powder, and a C powder) is prepared. Each of these powders desirably has a particle diameter of 0.5 μm or more and 10 μm or less. A too small particle diameter of the raw material powder facilitates oxidation to cause, for example, a problem of increasing the oxygen concentration in the sputtering target. Accordingly, the particle diameter is desirably 0.5 μm or more. In contrast, if these raw material powders have large particle diameters, it is difficult to finely disperse C particles in the alloy. Accordingly, the particle diameter is further desirably 10 μm or less.

Furthermore, as the raw material powder, an alloy powder (a Fe—Pt powder) may be used. In particular, though it varies depending on the composition, an alloy powder containing Pt is effective for reducing the amount of oxygen in the raw material powders. In also the case of using an alloy powder, the powder desirably has a particle diameter of 0.5 μm or more and 10 μm or less.

It is desirable to mix prescribed titanium oxide (TiO₂) and C in advance with a high-energy mixing medium such as a ball mill. In such a case, formation of solid solution of TiO₂ and C is enhanced to improve the sinterability.

Alternatively, a predetermined amount of titanium oxide may be added to a Fe—Pt—C powder mixture, and the resulting mixture may be pulverized and mixed with, for example, a ball mill into a raw material powder for sintering. Furthermore, titanium oxide can also be used as a pulverization medium of a ball mill.

The additional element composed of at least one element selected from B, Ru, Ag, Au, and Cu and the additive composed of at least one oxide selected from SiO₂, Cr₂O₃, CoO, Ta₂O₅, B₂O₃, MgO, and Co₃O₄ are preferably added when the raw material powders of the main components are mixed and are preferably mixed together.

Subsequently, the above-mentioned powders are weighed to give a desired composition and are mixed and pulverized by a known technique such as a ball mill.

The thus-prepared powder mixture is molded and sintered by hot pressing. Instead of the hot pressing, plasma arc sintering or hot hydrostatic pressure sintering may be employed. Though it varies depending on the composition of a sputtering target, the retention temperature for the sintering is in a range of 1100° C. to 1400° C. in many cases.

The sintered compact taken out from the hot press is subjected to hot isostatic pressing. The hot isostatic pressing is effective for increasing the density of the sintered compact. Though it varies depending on the composition of the sintered compact, the retention temperature for the hot isostatic pressing is in the range of 1100° C. to 1400° C. in many cases. The applied pressure is set to 100 MPa or more.

The thus-prepared sintered compact is processed into a desired shape with a lathe to give the sputtering target of the present invention.

As a result, a C particle dispersed Fe—Pt-based sputtering target including C particles uniformly and finely dispersed in an alloy and having a high density can be produced. The thus-produced sputtering target of the present invention is useful as a sputtering target for forming a granular magnetic thin film.

### EXAMPLES

The present invention will now be described by examples and comparative examples. These examples are merely exemplary and are not intended to limit the scope of the invention. That is, the present invention is limited only by the claims and encompasses various modifications in addition to examples included in the present invention.

### Example 1

A Fe powder having an average particle diameter of 3 μm, a Pt powder having an average particle diameter of 3 μm, a C powder having an average particle diameter of 1 μm, and a TiO₂ powder having an average particle diameter of 1 μm were prepared as raw material powders. The C powder used was commercially available amorphous carbon.

These powders were weighed to give a composition of 41Fe-40Pt-9TiO₂-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 98.5%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. FIG. 1 shows images of such appearance to confirm the results. The average area per particle in the portion other than the alloy phase of the sputtering target was 0.82 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 85.

### Example 2

A Fe powder having an average particle diameter of 3 μm, a Pt powder having an average particle diameter of 3 μm, a C powder having an average particle diameter of 1 μm, and a TiO₂ powder having an average particle diameter of 1 μm were prepared as raw material powders. The C powder used was commercially available amorphous carbon. These powders were weighed to give a composition of 29Fe-60Pt-1TiO₂-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 98.1%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.75 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 95.

### Example 3

A Fe powder having an average particle diameter of 3 μm, a Pt powder having an average particle diameter of 3 μm, a C powder having an average particle diameter of 1 μm, and a TiO₂ powder having an average particle diameter of 1 μm were prepared as raw material powders. The C powder used was commercially available amorphous carbon.

These powders were weighed to give a composition of 69Fe-10Pt-20TiO₂-1C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1100° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 99.4%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area in the portion other than the alloy phase of the sputtering target was 5.25 μm².

The average area in the portion other than the alloy phase of the sputtering target of Example 3 was considerably larger than that of the sputtering target of Example 2. This is caused by that TiO₂ is prone to be connected to each other (prone to aggregate) compared to C. It is consequently believed that in Example 3 in which the amount of TiO₂ is high, the area of the portion other than the alloy phase was large.

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering to conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 24.

### Example 4

A Fe powder having an average particle diameter of 3 μm, a Pt powder having an average particle diameter of 3 μm, a C powder having an average particle diameter of 1 μm, a TiO₂ powder having an average particle diameter of 1 μm, a SiO₂ powder having an average particle diameter of 1 μm, and a Cr₂O₃ powder having an average particle diameter of 3 μm were prepared as raw material powders. The C powder used was commercially available amorphous carbon.

These powders were weighed to give a composition of 50Fe-40Pt-5TiO₂-2SiO₂-2Cr₂O₃-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 98.3%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.68 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 55.

### Example 5

A Fe powder having an average particle diameter of 3 μm, a Pt powder having an average particle diameter of 3 μm, a C powder having an average particle diameter of 1 μm, a TiO₂ powder having an average particle diameter of 1 μm, a B₂O₃ powder having an average particle diameter of 1 μm, a Ta₂O₅ powder having an average particle diameter of 3 μm, and a CoO powder having an average particle diameter of 1 μm were prepared as raw material powders. The C powder used was commercially available amorphous carbon.

These powders were weighed to give a composition of 40Fe-40Pt-5TiO₂-2B₂O₃-1Ta₂O₅-1CoO-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 98.7%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.92 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 65.

### Example 6

A Fe powder having an average particle diameter of 3 μm, a Pt powder having an average particle diameter of 3 μm, a C powder having an average particle diameter of 1 μm, a TiO₂ powder having an average particle diameter of 1 μm, a B₂O₃ powder having an average particle diameter of 1 μm, a Ta₂O₅ powder having an average particle diameter of 1 μm, and a CoO powder having an average particle diameter of 1 μm were prepared as raw material powders. The C powder used was commercially available amorphous carbon.

These powders were weighed to give a composition of 50Fe-40Pt-5TiO₂-2MgO-2Co₃O₄-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 98.6%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.85 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 96.

### Example 7

A Fe powder having an average particle diameter of 3 μm, a Pt powder having an average particle diameter of 3 μm, a C powder having an average particle diameter of 1 μm, a TiO₂ powder having an average particle diameter of 1 μm, and a Ru powder having an average particle diameter of 8 μm were prepared as raw material powders. The C powder used was commercially available amorphous carbon.

These powders were weighed to give a composition of 39Fe-39Pt-9TiO₂-3Ru-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 98.4%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.84 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 81.

### Example 8

A Fe powder having an average particle diameter of 3 μm, a Pt powder having an average particle diameter of 3 μm, a C powder having an average particle diameter of 1 μm, a TiO₂ powder having an average particle diameter of 1 μm, and a Au powder having an average particle diameter of 5 μm were prepared as raw material powders. The C powder used was commercially available amorphous carbon.

These powders were weighed to give a composition of 38Fe-38Pt-9TiO₂-5Au-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 97.6%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 1.22 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 97.

### Example 9

A Fe powder having an average particle diameter of 3 μm, a Pt powder having an average particle diameter of 3 μm, a C powder having an average particle diameter of 1 μm, a TiO₂ powder having an average particle diameter of 1 μm, and a Ag powder having an average particle diameter of 5 μm were prepared as raw material powders. The C powder used was commercially available amorphous carbon.

These powders were weighed to give a composition of 40.5Fe-40Pt-9TiO₂-0.5Ag-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 97.1%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.92 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 101.

### Example 10

A Fe powder having an average particle diameter of 3 μm, a Pt powder having an average particle diameter of 3 μm, a C powder having an average particle diameter of 1 μm, a TiO₂ powder having an average particle diameter of 1 μm, and a Cu powder having an average particle diameter of 5 μm were prepared as raw material powders. The C powder used was commercially available amorphous carbon.

These powders were weighed to give a composition of 37Fe-37Pt-9TiO₂-7Cu-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 98.1%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.8 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 82.

### Example 11

A Fe powder having an average particle diameter of 3 μm, a Pt powder having an average particle diameter of 3 μm, a C powder having an average particle diameter of 1 μm, a TiO₂ powder having an average particle diameter of 1 μm, and a Co—B powder having an average particle diameter of 6 μm were prepared as raw material powders. The C powder used was commercially available amorphous carbon.

These powders were weighed to give a composition of 40Fe-40Pt-9TiO₂-1B-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 98.7%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.86 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 79.

### Example 12

A Fe powder having an average particle diameter of 3 μm, a Pt powder having an average particle diameter of 3 μm, a C powder having an average particle diameter of 1 μm, and a TiO₂ powder having an average particle diameter of 1 μm were prepared as raw material powders. The C powder used was commercially available amorphous carbon. These powders were weighed to give a composition of 30Fe-25Pt-5TiO₂-40C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber.

Subsequently, the sintered compact taken out from the mold for hot pressing was hot isostatic pressed. The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 97.9%.

The polished surface of the sputtering target was subjected to element mapping to investigate the insides of regions where both titanium (Ti) and oxygen (O) are detected and regions where C is detected. The results demonstrated that the regions where C was detected exist in the regions where both titanium (Ti) and oxygen (O) were detected to show the inclusion of a part of C. The average area per particle in the portion other than the alloy phase of the sputtering target was 0.73 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles adhered onto the substrate was counted with a particle counter. The number of particles having a particle diameter of 0.25 to 3 μm was 162.

### Comparative Example 1

A Fe powder having an average particle diameter of 3 μm, a Pt powder having an average particle diameter of 3 μm, and a C powder having an average particle diameter of 1 μm were prepared as raw material powders. The C powder used was commercially available amorphous carbon. These powders were weighed to give a composition of 45Fe-45Pt-10C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber. Subsequently, the sintered compact taken out from the mold for hot pressing was hot isostatic pressed.

The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 95.5%. The average area per particle in the portion other than the alloy phase of the sputtering target was 0.74 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles having a particle diameter of 0.25 to 3 μm adhered onto the substrate was counted with a particle counter. The number of the particles was 1050.

### Comparative Example 2

A Fe powder having an average particle diameter of 3 μm, a Pt powder having an average particle diameter of 3 μm, and a C powder having an average particle diameter of 1 μm were prepared as raw material powders. The C powder used was commercially available amorphous carbon. These powders were weighed to give a composition of 30Fe-30Pt-40C (mol %) and a total weight of 2600 g.

Subsequently, the weighed powders were put in a 10-Liter ball mill pot together with titania balls as a pulverizing medium, and the mill pot was sealed and rotated for 4 hours for mixing and pulverization. The powder mixture taken out from the ball mill was packed in a carbon mold and was hot pressed.

The hot pressing was performed under conditions of a vacuum atmosphere, a rate of temperature increase of 300° C./hour, a retention temperature of 1200° C., a retention time of 2 hours, and a pressure of 30 MPa from the start of the increase in temperature until the end of the retention. After the completion of the retention, the hot pressed powder was naturally cooled inside the chamber. Subsequently, the sintered compact taken out from the mold for hot pressing was hot isostatic pressed.

The conditions of the hot isostatic pressing were a rate of temperature increase of 300° C./hour, a retention temperature of 1100° C., and a retention time of 2 hours, with gradually increasing the Ar gas pressure from the start of the increase in temperature and maintaining the Ar gas pressure at 150 MPa during the retention at 1100° C. After the completion of the retention, the sintered compact was naturally cooled inside the furnace.

The density of the thus-produced sintered compact was measured by an Archimedes method, and the relative density calculated was 95.1%. The average area per particle in the portion other than the alloy phase of the sputtering target was 0.71 μm².

Subsequently, the sintered compact was cut with a lathe into a shape having a diameter of 180.0 mm and a thickness of 5.0 mm and was set in a magnetron sputtering apparatus (C-3010 sputtering system, manufactured by Canon Anelva Corporation) and was sputtered.

After presputtering at 2 kWhr, a film was formed under sputtering conditions of an applied power of 1 kW and an Ar gas pressure of 1.7 Pa on a silicon substrate having a diameter of 4 inches at 1 kW for 20 seconds. The number of particles having a particle diameter of 0.25 to 3 μm adhered onto the substrate was counted with a particle counter. The number of the particles was 2120.

Table 1 shows a list of the compositions and the resulting average areas of portions other than alloy phases, relative densities, and the numbers of particles, in Examples and Comparative Examples.

TABLE 1

| | | Average area | | |
|---|---|---|---|---|
| | | per particle in portion | Relative | |
| | | other than alloy phase | density | Number of |
| | Composition (mol %) | (μm²) | (%) | particles |
| Example 1 | 41Fe—40Pt—9TiO₂—10C | 0.82 | 98.5 | 85 |
| Comparative | 45Fe—45Pt—10C | 0.74 | 95.5 | 1050 |
| Example 1 | | | | |
| Example 2 | 29Fe—60Pt—1TiO₂—10C | 0.75 | 98.1 | 95 |
| Example 3 | 69Fe—10Pt—20TiO₂—1C | 5.25 | 99.4 | 24 |
| Example 4 | 50Fe—40Pt—5TiO₂—2SiO₂—2Cr₂O₃—10C | 0.68 | 98.3 | 55 |
| Example 5 | 40Fe—40Pt—5TiO₂—2B₂O₃—1Ta₂O₅—1CoO—10C | 0.92 | 98.7 | 65 |
| Example 6 | 50Fe—40Pt—5TiO₂—2MgO—2Co₃O₄—10C | 0.85 | 98.6 | 96 |
| Example 7 | 39Fe—39Pt—9TiO₂—3Ru—10C | 0.84 | 98.4 | 81 |
| Example 8 | 38Fe—38Pt—9TiO₂—5Au—10C | 1.22 | 97.6 | 97 |
| Example 9 | 40.5Fe—40Pt—9TiO₂—0.5Ag—10C | 0.92 | 97.1 | 101 |
| Example 10 | 37Fe—37Pt—9TiO₂—7Cu—10C | 0.8 | 98.1 | 82 |
| Example 11 | 40Fe—40Pt—9TiO₂—1B—10C | 0.86 | 98.7 | 79 |
| Example 12 | 30Fe—25Pt—5TiO₂—40C | 0.73 | 97.9 | 162 |
| Comparative | 30Fe—30Pt—40C | 0.71 | 95.1 | 2120 |
| Example 2 | | | | |

As obvious from the above-described examples, it is revealed that sputtering targets having compositions within the numerical value ranges of components of the present invention have high densities and are low in the numbers of occurring particles. It is revealed that in the sputtering targets not containing titanium oxide of Comparative Examples 1 and 2, the densities are low and the numbers of particles are very large.

Among Examples, in Example 12, the content of C particles was 40 mol %, which is the upper limit. Consequently, the number of particles was 162 and was slightly larger than those in other Examples. However, the number is within the permissible range and is not a particular problem.

In Example 2, the content of titanium oxide was 1 mol %, which was slightly low compared to that of C. Consequently, the number of particles was 95 and was slightly larger than those in other Examples. However, the number is within the permissible range and is not a problem.

It can be concluded that in a titanium oxide content of 0.05 to 20 mol %, a sputtering target for forming a magnetic thin film having a satisfactory granular structure can be provided.

The sputtering target of the present invention can further contain 0.5 mol % or more and 20 mol % or less of at least one additional element selected from B, Ru, Ag, Au, and Cu and also 0.5 mol % or more and 20 mol % or less of at least one oxide additive selected from SiO₂, Cr₂O₃, CoO, Ta₂O₅, B₂O₃, MgO, and Co₃O₄. It can be readily confirmed from Examples that the sputtering targets containing these additives within prescribed ranges have characteristics equivalent to those of a sputtering target not containing these additives. The present invention encompasses all of these targets.

The present invention allows production of a granular magnetic thin film without using any high-cost co-sputtering apparatuses and has an excellent effect of providing a C particle dispersed Fe—Pt-based sputtering target having a high density and reducing the amount of particles generated during sputtering. Accordingly, the present invention is useful as a sputtering target for forming a magnetic thin film having a granular structure.

1. A sputtering target for a magnetic recording film, the sputtering target comprising 5 mol % or more and 60 mol % or less of Pt, 0.1 mol % or more and 40 mol % or less of C, 0.05 mol % or more and 20 mol % or less of titanium oxide, and Fe.

2. The sputtering target for a magnetic recording film according to claim 1, wherein titanium oxide particles are dispersed in the target; and the C is partially solid-soluted in the titanium oxide particles or is partially included in oxide particles.

3. The sputtering target according to claim 1, wherein element mapping of a polished surface of the sputtering target shows that a region where both titanium (Ti) and oxygen (O) are detected includes a part of a region where C is detected.

4. The sputtering target for a magnetic recording film according to claim 2, the sputtering target further comprising 0.5 mol % or more and 20 mol % or less of at least one additional element selected from B, Ru, Ag, Au, and Cu.

5. The sputtering target for a magnetic recording film according to claim 4, the sputtering target further comprising 0.5 mol % or more and 20 mol % or less of at least one oxide additive selected from SiO₂, Cr₂O₃, CoO, Ta₂O₅, B₂O₃, MgO, and Co₃O₄.

6. The sputtering target for a magnetic recording film according to claim 5, wherein the sputtering target has a relative density of 97% or more.

7. The sputtering target for a magnetic recording film according to claim 1, wherein the sputtering target further comprises 0.5 mol % or more and 20 mol % or less of at least one additional element selected from B, Ru, Ag, Au, and Cu.

8. The sputtering target for a magnetic recording film according to claim 1, wherein the sputtering target further comprises 0.5 mol % or more and 20 mol % or less of at least one oxide additive selected from SiO₂, Cr₂O₃, CoO, Ta₂O₅, B₂O₃, MgO, and CO₃O₄.

9. The sputtering target for a magnetic recording film according to claim 1, wherein the sputtering target has a relative density of 97% or more.

10. A sputtering target for a magnetic recording film, the sputtering target comprising 5 mol % or more and 60 mol % or less of Pt, 0.1 mol % or more and 40 mol % or less of C, 0.05 mol % or more and 20 mol % or less of titanium oxide, 0.5 mol % or more and 20 mol % or less of at least one oxide additive selected from SiO₂, Cr₂O₃, CoO, Ta₂O₅, B₂O₃, MgO, and Co₃O₄, and the remainder being Fe.

11. The sputtering target for a magnetic recording film according to claim 10, wherein titanium oxide particles are dispersed in the target; and the C is partially solid-soluted in the titanium oxide particles or is partially included in oxide particles.

12. The sputtering target according to claim 10, wherein element mapping of a polished surface of the sputtering target shows that a region where both titanium (Ti) and oxygen (O) are detected includes a part of a region where C is detected.

13. The sputtering target for a magnetic recording film according to claim 10, wherein the sputtering target has a relative density of 97% or more.

14. A sputtering target for a magnetic recording film, the sputtering target comprising 5 mol % or more and 60 mol % or less of Pt, 0.1 mol % or more and 40 mol % or less of C, 0.05 mol % or more and 20 mol % or less of titanium oxide, 0.5 mol % or more and 20 mol % or less of at least one additional element selected from B, Ru, Ag, Au, and Cu; and the remainder being Fe.

15. The sputtering target for a magnetic recording film according to claim 14, wherein titanium oxide particles are dispersed in the target; and the C is partially solid-soluted in the titanium oxide particles or is partially included in oxide particles.

16. The sputtering target according to claim 14, wherein element mapping of a polished surface of the sputtering target shows that a region where both titanium (Ti) and oxygen (O) are detected includes a part of a region where C is detected.

17. The sputtering target for a magnetic recording film according to claim 14, wherein the sputtering target has a relative density of 97% or more.
